(19) United States
(12) Patent Application Publication
(10) Pub. No.: US 2020/0052067 A1
(43) Pub. Date: Feb. 13, 2020

(54) SEMICONDUCTOR STRUCTURE AND METHOD FOR PREPARING THE SAME

(71) Applicant: NANYA TECHNOLOGY CORPORATION, New Taipei City (TW)

(72) Inventor: Chung-Lin HUANG, Taoyuan City (TW)

(21) Appl. No.: 16/102,125

(22) Filed: Aug. 13, 2018

(51) Int. Cl. H01L 29/06; H01L 21/762

(52) U.S. Cl. CPC H01L 29/0649; H01L 21/76224

(57) ABSTRACT

The present disclosure provides a semiconductor structure. The semiconductor structure includes a substrate, a plurality of first isolation structures disposed on the substrate, and a plurality of first semiconductor islands disposed on the substrate and separated from each other by the plurality of first isolation structures. In some embodiments, each of the plurality of first isolation structures includes a first bottom surface in contact with the substrate and a first top surface opposite to the first bottom surface. In some embodiments, a width of the first bottom surface is greater than a width of the first top surface.

### TECHNICAL FIELD

The present disclosure relates to a semiconductor structure and a method for preparing the same, and more particularly, to a semiconductor structure includes semiconductor islands and a method for preparing the same.

### DISCUSSION OF THE BACKGROUND

In semiconductor manufacturing processes, photolithography techniques are commonly adopted to define structures. Typically, an integrated circuit layout is designed and outputted onto one or more photomasks. The integrated circuit layout is transferred from the photomasks to a mask layer to form a mask pattern, and then transferred from the mask pattern to a target layer. However, with the advancing miniaturization and integration requirements of semiconductor devices, including memory devices such as dynamic random access memories (DRAMs), flash memories, static random access memories (SRAMs), and ferroelectric (FE) memories, the semiconductor structures and features of such devices become more miniaturized as well. Accordingly, the continual reduction in semiconductor structure and feature sizes places ever-greater demands on the techniques used to form the structures and features.

For example, to form active regions in the substrate, a plurality of trenches are formed by etching the substrate, and a plurality of island structures, which are used to form the active regions, are obtained and separated from each other by the trenches. Insulating materials are then deposited to fill the trenches and to form a plurality of isolation structures to define and provide electrical isolation between the island structures. However, it is often found that the thin, slim island structures may topple or collapse before the filling of the trenches and the forming of the isolation structures. Further, the island structures may lean or collapse due to stress from the insulating material filled therebetween. Consequently, reliability and performance of a device that includes an island structure and an active region are reduced.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a semiconductor structure. The semiconductor structure includes a substrate, a plurality of first isolation structures disposed on the substrate, and a plurality of first semiconductor islands disposed on the substrate and separated from each other by the plurality of first isolation structures. In some embodiments, each of the plurality of first isolation structures includes a first bottom surface in contact with the substrate and a first top surface opposite to the first bottom surface. In some embodiments, a width of the first bottom surface is greater than a width of the first top surface.

In some embodiments, a height-to-width ratio of the plurality of first semiconductor islands is between approximately 10 and approximately 30.

In some embodiments, each of the plurality of first semiconductor islands includes a first portion disposed on the substrate and a second portion disposed on the first portion. In some embodiments, a height of the second portion is greater than a height of the first portion.

In some embodiments, a bottom surface of the first portion is lower than the first bottom surface of the first isolation structure.

In some embodiments, the second portion is electrically isolated from the substrate by the first portion.

In some embodiments, the second portion includes dopants of a first conductivity type.

In some embodiments, the first portion is un-doped.

In some embodiments, the first portion includes dopants of a second conductivity type, and the second conductivity type is complementary to the first conductivity type.

In some embodiments, the semiconductor structure further includes a second isolation structure disposed on the substrate, and at least a second semiconductor island disposed on the substrate and separated from the plurality of first semiconductor islands by the second isolation structure. In some embodiments, the second isolation structure includes a second bottom surface in contact with the substrate and a second top surface opposite to the second bottom surface. In some embodiments, a width of the second bottom surface is greater than a width of the second top surface.

In some embodiments, the width of second bottom surface of the second isolation structure is greater than the width of the first bottom surface of the first isolation structure, and the width of the second top surface of the second isolation structure is greater than the width of the first top surface of the first isolation structure.

Another aspect of the present disclosure provides a method for preparing a semiconductor structure. The method includes the following steps. A substrate is provided. A mesh-like isolation structure is formed on the substrate. In some embodiments, the mesh-like isolation structure includes a plurality of first openings exposing the substrate. A plurality of first semiconductor islands are formed to fill the plurality of first openings. In some embodiments, each of the plurality of first semiconductor islands has a bottom surface in contact with the substrate and a top surface opposite to the bottom surface. In some embodiments, a width of the top surface of the first semiconductor islands is greater than a width of the bottom surface of the first semiconductor islands.

In some embodiments, the method further includes the following steps. An insulating layer is formed on the substrate, and portions of the insulating layer are removed to form the plurality of first openings.

In some embodiments, the method further includes a step of removing portions of the substrate exposed through the plurality of first openings of the mesh-like isolation structure to form a plurality of recesses in the substrate. In some embodiments, each of the plurality of recesses is under and coupled to one of the plurality of first openings.

In some embodiments, the forming of the plurality of first semiconductor islands further includes the following steps. A first portion of each of the plurality of first semiconductor islands is formed in each recess. A second portion of each of the plurality of first semiconductor islands is formed on each first portion in each first opening.

In some embodiments, the second portion is doped with dopants of a first conductivity type, and the first portion is un-doped.

In some embodiments, the second portion is doped with dopants of a first conductivity type, and the first portion is doped with a second conductivity type. In some embodiments, the second conductivity type is complementary to the first conductivity type.

In some embodiments, a bottom surface of the first portion is lower than a bottom surface of the mesh-like isolation structure.

In some embodiments, a height of the second portion is greater than a height of the first portion.

In some embodiments, the mesh-like isolation structure further includes at least a second opening. In some embodiments, a width of the second opening is greater than a width of the plurality of first openings

In some embodiments, the method further includes a step of forming a second semiconductor island to fill the second opening simultaneously with the forming of the plurality of first semiconductor islands.

In the present disclosure, the mesh-like isolation structure is formed on the substrate. Due to the mesh-like configuration, a structural strength of the isolation structure is improved such that collapsing and toppling are prevented. Further, the plurality of semiconductor islands, which serve as an active region for memory cells, can be easily formed in the mesh-like isolation structure. Accordingly, collapsing and toppling of the thin, slim semiconductor islands are avoided, and thus reliability and performance of a device that includes the semiconductor islands are improved.

In contrast, with a comparative method, the semiconductor islands are formed on the substrate and vacancies between the semiconductor islands are subsequently filled with the isolation structure. The semiconductor islands often topple or collapse due to their thin and slim configuration and due to the stress generated during the forming of the isolation structure, and thus reliability and performance of a device that includes the semiconductor islands are adversely impacted.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a flow diagram illustrating a method for preparing a semiconductor structure, in accordance with a first embodiment of the present disclosure.

FIGS. 2A to 2C are schematic diagrams illustrating various fabrication stages of the method for preparing the semiconductor structure in accordance with the first embodiment of the present disclosure.

FIG. 3 is a flow diagram illustrating a method for preparing a semiconductor structure, in accordance with a second embodiment of the present disclosure.

FIGS. 4A to 4E are schematic diagrams illustrating various fabrication stages of the method for preparing the semiconductor structure in accordance with the second embodiment of the present disclosure.

FIG. 5 is a top view of a portion of the semiconductor structure in accordance with the first and second embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, is layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

As used herein, the terms “patterning” or “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer. The patterning process includes forming a mask on the existing film or layer and removing the unmasked film or layer with an etch or other removal process. The mask can be a photoresist or a hard mask. In some embodiments, a patterning process is adopted to form a patterned layer directly on a surface. The patterning process includes forming a photosensitive film on the surface, conducting a photolithography process, and performing a developing process. The remaining photosensitive film is retained and integrated into the semiconductor device.

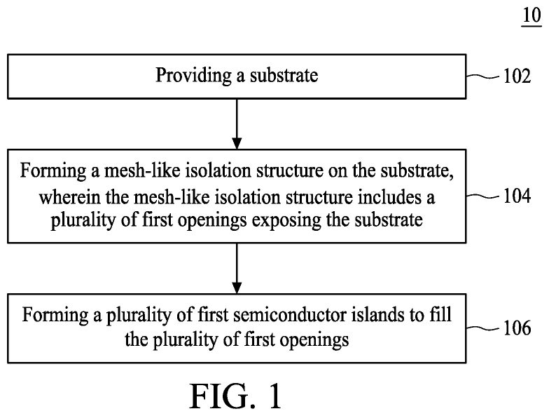

FIG. 1 is a flow diagram illustrating a method for preparing a semiconductor structure, in accordance with a first embodiment of the present disclosure. The method for preparing the semiconductor structure 10 includes a step 102, providing a substrate. The method for preparing the semiconductor structure 10 further includes a step 104, forming a mesh-like isolation structure on the substrate. In some embodiments, the mesh-like isolation structure includes a plurality of first openings exposing the substrate. The method for preparing the semiconductor structure 10 further includes a step 106, forming a plurality of first semiconductor islands to fill the plurality of first openings. In some embodiments, each of the plurality of first semiconductor islands has a bottom surface in contact with the substrate and a top surface opposite to the bottom surface, wherein a width of the top surface is greater than a width of the bottom surface. The method for preparing the semiconductor structure 10 will be further described according to the first embodiment.

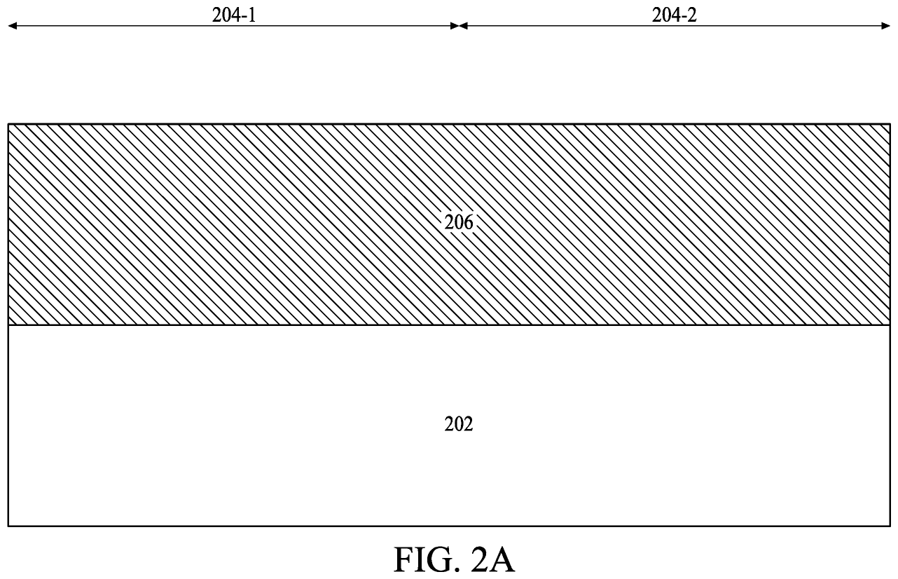

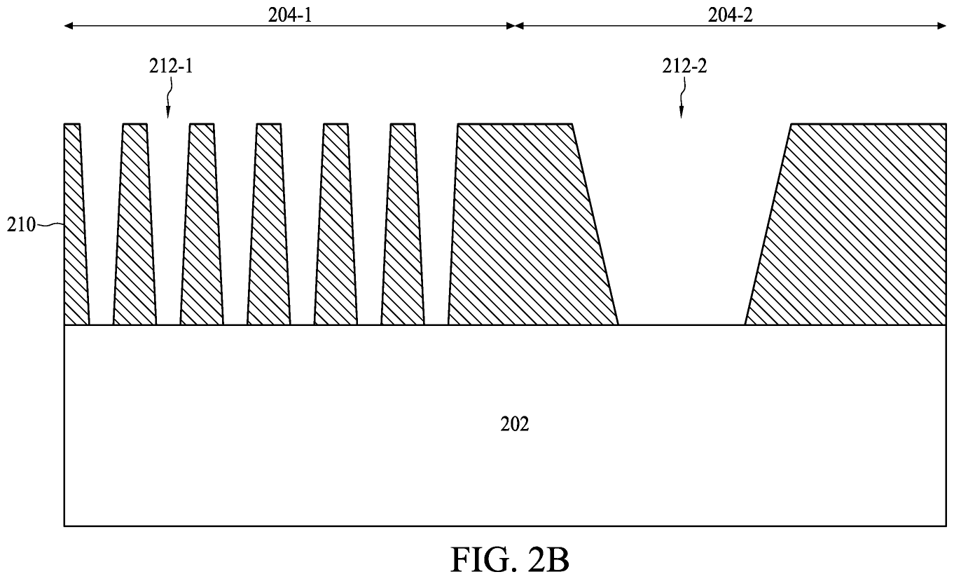

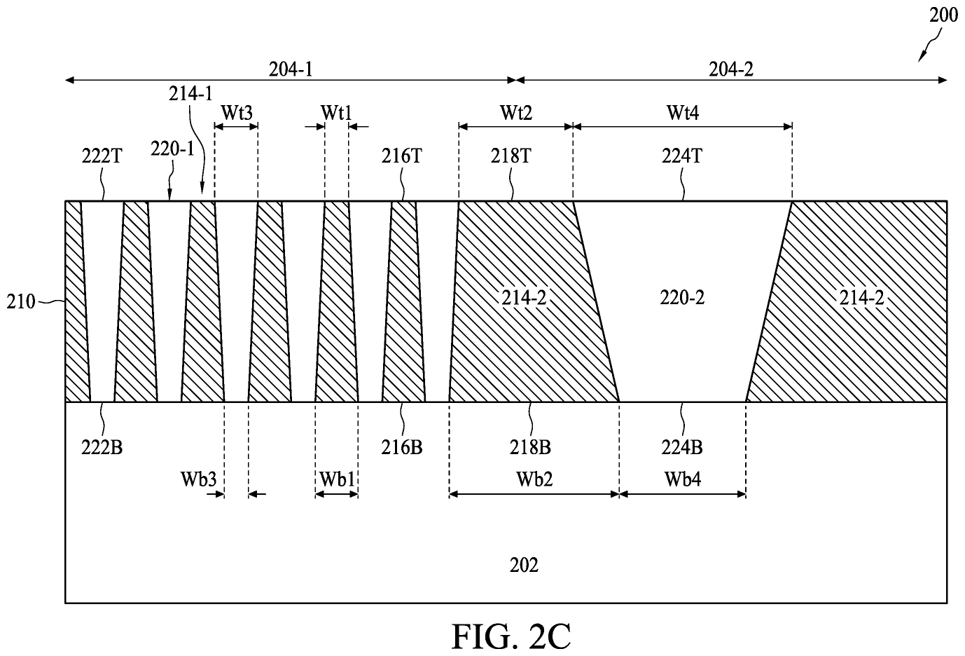

FIGS. 2A to 2C are schematic diagrams illustrating various fabrication stages constructed according to the method for preparing the semiconductor structure in accordance with the first embodiment of the present disclosure. Referring to FIG. 2A, a substrate 202 is provided according to step 102. The substrate 200 can include silicon (Si), gallium (Ga), gallium arsenide (GaAs), gallium nitride (GaN), strained silicon, silicon-germanium (SiGe), silicon carbide (SiC), diamond, epitaxy layer or a combination thereof, but the disclosure is not limited thereto. In some embodiments, the substrate 202 can have a first region 204-1 and a second region 204-2 defined thereon. In some embodiments, the first region 204-1 can be an array region where memory cells are to be formed, and the second region 204-2 can be a peripheral region, but the disclosure is not limited thereto.

Still referring to FIG. 2A, an insulating layer 206 is formed on the substrate 202. In some embodiments, the insulating layer 206 can include silicon oxide (SiO), but the disclosure is not limited thereto. In some embodiments, a thickness of the insulating layer 206 can be between approximately 10 nm and approximately 500 nm, but the disclosure is not limited thereto. In some embodiments, a patterned hard mask (not shown) can be formed on the insulating layer 206. In some embodiments of the present disclosure, the patterned hard mask can include a single-layer or a multi-layered structure.

Referring to FIG. 2B, portions of the insulating layer 206 are removed through the patterned hard mask, and thus a mesh-like isolation structure 210 is formed on the substrate 202 according to step 104. In some embodiments, the mesh-like isolation structure 210 includes a plurality of first openings 212-1 exposing the substrate 202, as shown in FIG. 2B. In some embodiments, a width of the plurality of first openings 212-1 can be between approximately 2 nm and approximately 20 nm, but the disclosure is not limited thereto. In some embodiments, the mesh-like isolation structure 210 further includes a second opening 212-2 exposing the substrate 202. Further, a width of the second opening 212-2 is greater than the width of each of the plurality of first openings 212-1, as shown in FIG. 2B. In some embodiments, the plurality of first openings 212-1 are all formed in the first region 204-1, while the second opening 212-2 is formed in the second region 204-2, but the disclosure is not limited thereto.

Referring to FIG. 2C, a plurality of first semiconductor islands 220-1 are formed to fill the plurality of first openings 212-1 according to step 106. In some embodiments, a second semiconductor island 220-2 is formed to fill the second opening 212-2, simultaneously with the forming of the first semiconductor islands 220-1. In some embodiments, the plurality of first semiconductor islands 220-1 and the second semiconductor island 220-2 are formed by selective epitaxial growth (SEG), but the disclosure is not limited thereto. In some embodiments, the plurality of first semiconductor islands 220-1 and the second semiconductor island 220-2 include epitaxial silicon, but the disclosure is not limited thereto. Further, the plurality of first semiconductor islands 220-1 and the second semiconductor island 220-2 can be doped with dopants of a first conductivity type before, during, or after the SEG. The first conductivity type can be a p type or an n type, depending on the product requirements. It should be noted that since the plurality of first semiconductor islands 220-1 are formed within the plurality of first openings 212-1, a height and a width of the plurality of first semiconductor islands 220-1 are similar to a depth and a width of the plurality of first openings 212-1, but the disclosure is not limited thereto. Since the second semiconductor island 220-2 is formed within the second opening 212-2, a height and a width of the first semiconductor island 220-1 are similar to a depth and the width of the second opening 212-2, but the disclosure is not limited thereto.

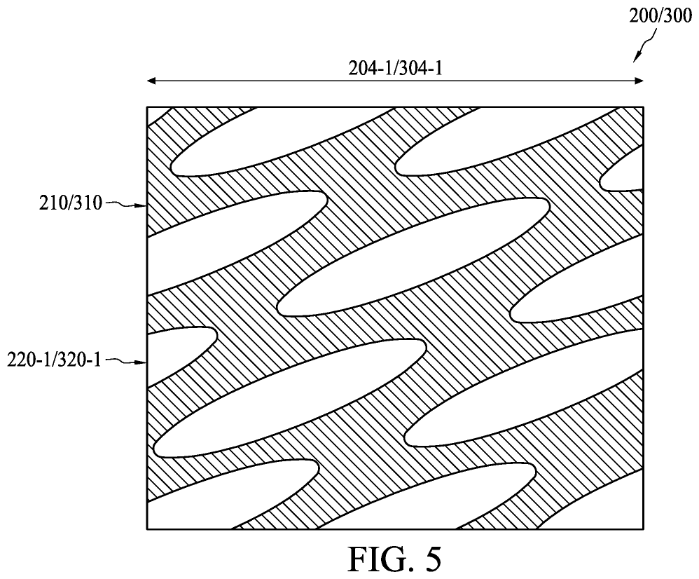

Accordingly, a semiconductor structure 200 is provided. Please refer to FIG. 2C and FIG. 5, wherein FIG. 5 is a top view of a portion of the semiconductor structure 200 in accordance with the first embodiment. The semiconductor structure 200 includes the substrate 202, the mesh-like isolation structure 210 disposed on the substrate 202, and the plurality of first semiconductor islands 220-1 disposed on the substrate 202. As shown in FIG. 2C, the substrate 202 includes the first region 204-1, for accommodation of memory cells, and the second the second region 204-2.

The mesh-like isolation structure 210 further includes a plurality of first isolation structures 214-1 located in the first region 204-1 and at least a second isolation structure 214-2 located in the second region 204-2. Each of the first isolation structures 214-1 includes a bottom surface 216B in contact with the substrate 202 and a top surface 216T opposite to the bottom surface 216B. Further, the top surface 216T is exposed, as shown in FIGS. 2C and 5. The top surface 216T has a width Wt1, the bottom surface 216B has a width Wb1, and the width Wb1 of the bottom surface 216B is greater than the width Wt1 of the top surface 216T, as shown in FIG. 2C. The second isolation structure 214-2 includes a bottom surface 218B in contact with the substrate 202 and a top surface 218T opposite to the bottom surface 218B. Similarly, the top surface 218T is exposed, as shown in FIG. 2C. The top surface 218T has a width Wt2, the bottom surface 218B has a width Wb2, and the width Wb2 of the bottom surface 218B is greater than the width Wt2 of the top surface 218T. The width Wt2 of the top surface 218T of the second isolation structure 214-2 is greater than the width Wt1 of the top surface 216T of the first isolation structures 214-1. The width Wb2 of the bottom surface 218B of the second isolation structure 214-2 is greater than the width Wb1 of the bottom surface 216B of the first isolation structures 214-1.

Still referring to FIGS. 2C and 5, the plurality of first semiconductor islands 220-1 are embedded within and separated from each other by the plurality of first isolation structures 214-1 in the first region 204-1. In some embodiments, a height-to-width aspect ratio of the plurality of first semiconductor islands 220-1 is greater than 10, but the disclosure is not limited thereto. In some embodiments, each of the first semiconductor islands 220-1 includes a bottom surface 222B in contact with the substrate 202 and a top surface 222T opposite to the bottom surface 222B. Further, the top surface 222T is exposed, as shown in FIGS. 2C and 5. The top surface 222T has a width Wt3, the bottom surface 222B has a width Wb3, and the width Wb3 of the bottom surface 222B of the first semiconductor island 220-1 is less than the width Wt3 of the top surface 222T of the first semiconductor island 220-1, as shown in FIG. 2C.

In some embodiments, the semiconductor structure 200 further includes at least a second semiconductor island 220-2 disposed in the second region 204-2. Further, the second semiconductor island 220-2 is physically and electrically separated from the plurality of first semiconductor islands 220-1 by the second isolation structure 214-2. In some embodiments, the second semiconductor island 220-2 includes a bottom surface 224B in contact with the substrate 202 and a top surface 224T opposite to the bottom surface 224B. Further, the top surface 224T is exposed, as shown in FIG. 2C. The top surface 224T has a width Wt4, the bottom surface 224B has a width Wb4, and the width Wb4 of the bottom surface 224B of the second semiconductor island 220-2 is less than the width Wt4 of the top surface 224T of the second semiconductor island 220-2, as shown in FIG. 2C. Further, both the width Wt4 of the top surface 224T and the width Wb4 of the bottom surface 224B of the second semiconductor island 220-2 are greater than the width Wt3 of the top surface 222T of the first semiconductor islands 220-1.

According to the semiconductor structure 200 and the method 10 for preparing the same, the mesh-like isolation structure 210 (including the first isolation structures 214-1 and the second isolation structure 214-2) is formed on the substrate 202 before the forming of the first and second semiconductor islands 220-1 and 220-2. Due to the mesh-like configuration, a structural strength of each of the first isolation structures 214-1 and the second isolation structure 214-2 is improved such that collapsing and toppling are prevented. Further, the plurality of first semiconductor islands 220-1, which serve as active region for memory cells, can be easily formed in the mesh-like isolation structure 210. Accordingly, collapsing and toppling of the thin, slim first semiconductor islands 220-1 are avoided, and thus reliability and performance of a device that includes the semiconductor islands are improved.

Further, the width Wb1 of the bottom surface 216B of the first isolation structures 214-1 is greater than the width Wt1 of the top surface 216T of the first isolation structures 214-1, and the width Wb2 of the bottom surface 218B of the second isolation structure 214-2 is greater than the width Wt2 of the top surface 218T of the second isolation structure 214-2. The trapezoidal configuration of the first and second isolation structures 214-1 and 214-2 increases resistance in the substrate 202 along sidewalls and the bottom surface 216B and 218B of the first and second isolation structures 214-1 and 214-2. Accordingly, the mesh-like isolation structure 210 provides better electrical isolation.

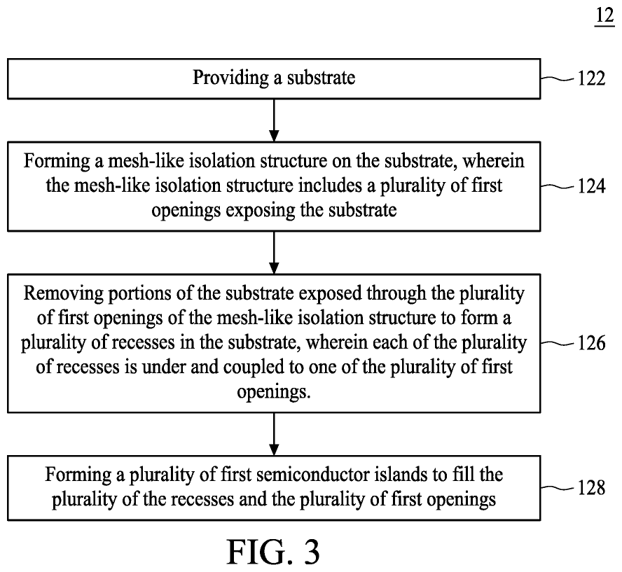

FIG. 3 is a flow diagram illustrating a method for preparing a semiconductor structure, in accordance with a second embodiment of the present disclosure. The method for preparing the semiconductor structure 12 includes a step 122, providing a substrate. The method for preparing the semiconductor structure 12 further includes a step 124, forming a mesh-like isolation structure on the substrate. In some embodiments, the mesh-like isolation structure includes a plurality of first openings exposing the substrate. The method for preparing the semiconductor structure 12 further includes a step 126, removing portions of the substrate exposed through the plurality of first openings of the mesh-like isolation structure to form a plurality of recesses in the substrate. In some embodiments, each of the plurality of recesses is under and coupled to one of the plurality of first openings. The method for preparing the semiconductor structure 12 further includes a step 128, forming a plurality of first semiconductor islands to fill the plurality of recesses and the plurality of first openings. In some embodiments, each of the plurality of first semiconductor islands has a bottom surface in contact with the substrate and a top surface opposite to the bottom surface, and a width of the top surface is greater than a width of the bottom surface. The method for preparing the semiconductor structure 12 will be further described according to the second embodiment.

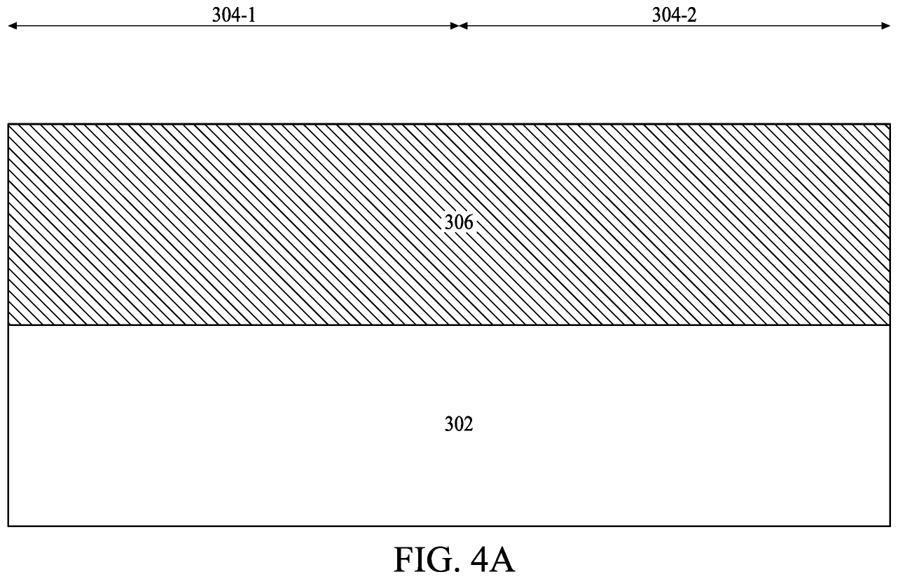

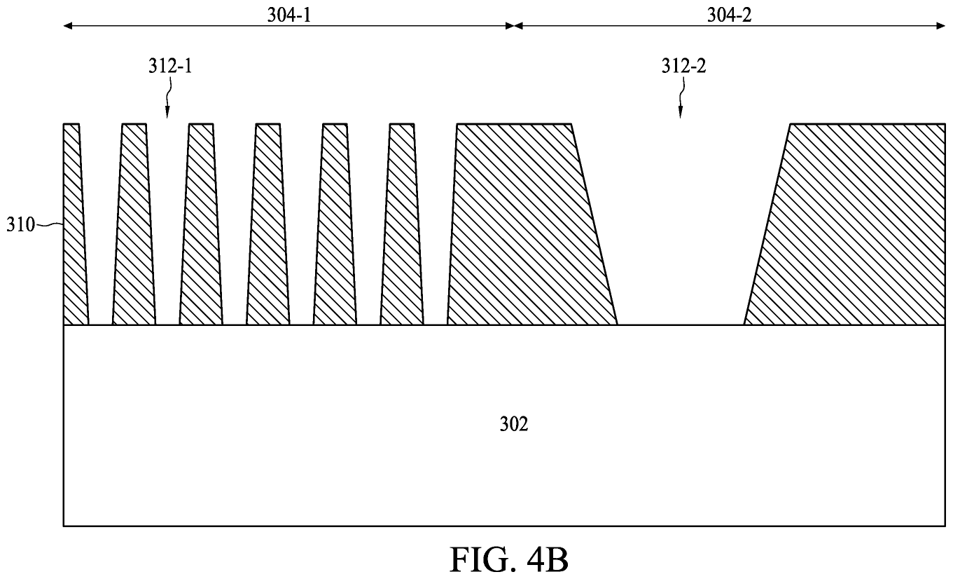

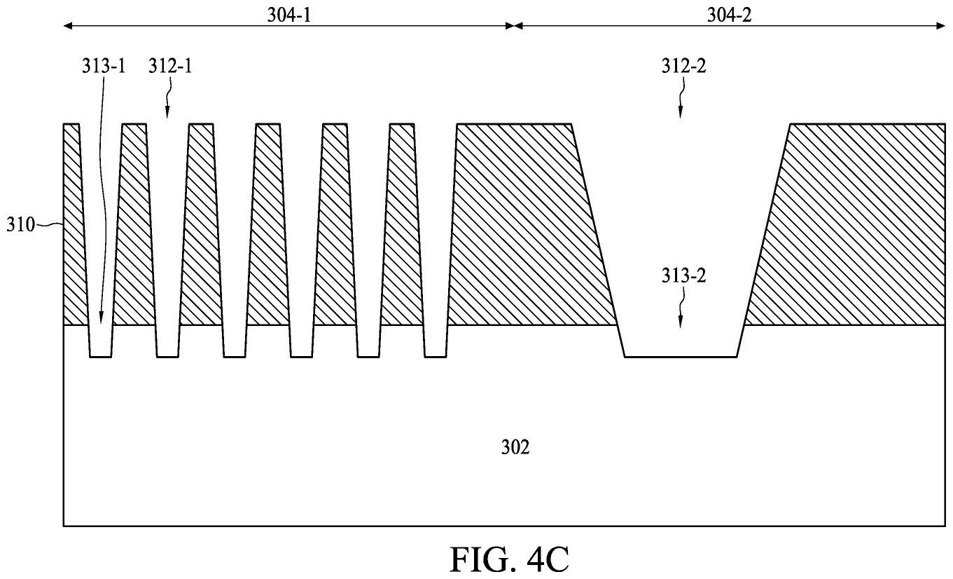

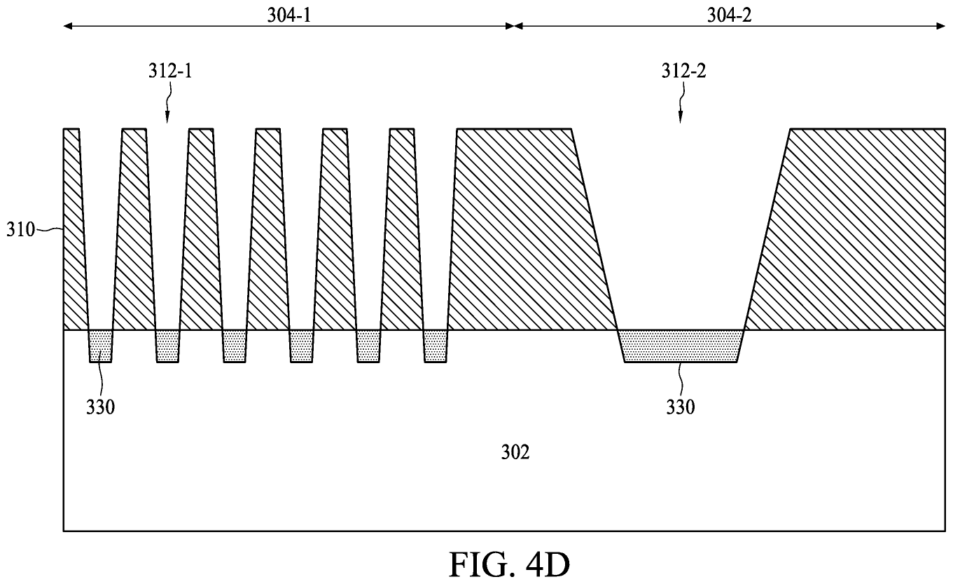

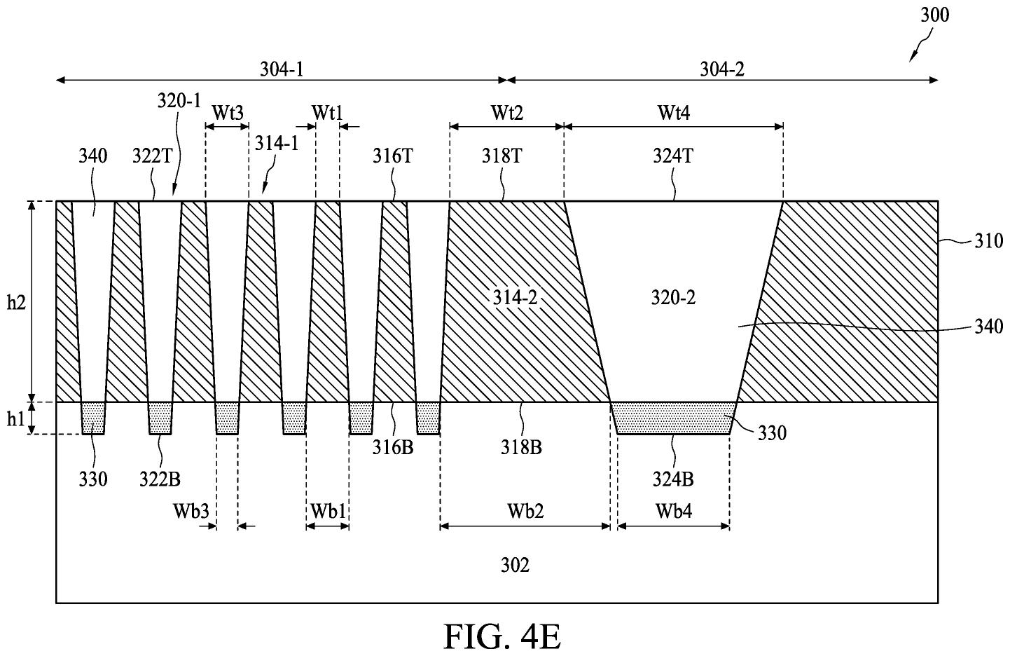

FIGS. 4A to 4E are schematic diagrams illustrating various fabrication stages constructed according to the method for preparing the semiconductor structure in accordance with the second embodiment of the present disclosure. It should be understood that similar features in the first and second embodiments can include similar materials, and thus such details are omitted in the interest of brevity. Further, those similar features are designated by the same numerals.

Referring to FIG. 4A, a substrate 302 is provided according to step 122. In some embodiments, the substrate 302 can have a first region 304-1 and a second region 304-2 defined thereon. In some embodiments, the first region 304-1 can be an array region where memory cells are to be formed, and the second region 304-2 can be a peripheral region, but the disclosure is not limited thereto. An insulating layer 306 is formed on the substrate 302, and a patterned hard mask (not shown) can be formed on the insulating layer 306.

Referring to FIG. 4B, portions of the insulating layer 306 are removed through the patterned hard mask, and thus a mesh-like isolation structure 310 is formed on the substrate 302 according to step 124. In some embodiments, the mesh-like isolation structure 310 includes a plurality of first openings 312-1 exposing the substrate 302, as shown in FIG. 4B. In some embodiments, a width of the plurality of first openings 312-1 can be between approximately 5 nm and approximately 50 nm, but the disclosure is not limited thereto. In some embodiments, the mesh-like isolation structure 310 further includes a second opening 312-2 exposing the substrate 302. Further, a width of the second opening 312-2 is greater than the width of each of the plurality of first openings 312-1, as shown in FIG. 4B. In some embodiments, the plurality of first openings 312-1 are all formed in the first region 304-1, while the second opening 312-2 is formed in the second region 304-2, but the disclosure is not limited thereto.

Referring to FIG. 4C, the portions of the substrate 302 exposed through the plurality of first openings 312-1 and the second opening to 312-2 are removed according to step 126. Accordingly, a plurality of recesses 313-1 and 313-2 are formed in the substrate 302. As shown in FIG. 4C, each of the plurality of recesses 313-1 is under and coupled to one of the plurality of first openings 312-1, while the recess 313-2 is under and coupled to the second opening 312-2. A bottom surface of each of the plurality of recesses 313-1 and 313-2 is lower than bottom surface of the mesh-like isolation structure 310. In some embodiments, a depth of each of the plurality of recesses 313-1 and 313-2 can be between approximately 5 nm and approximately 100 nm, but the disclosure is not limited thereto.

Referring to FIGS. 4D and 4E, a plurality of first semiconductor islands 320-1 are formed to fill the plurality of recesses 313-1 and the plurality of first openings 312-1 according to step 128. In some embodiments, a second semiconductor island 320-2 is formed to fill the recess 313-2 and the second opening 312-2 simultaneously.

In some embodiments, the forming of the first and second semiconductor islands 320-1 and 320-2 further includes the following steps. In some embodiments, a first portion 330 of each of the first and second semiconductor islands 320-1 and 320-2 is for red in each of the plurality of recesses 313-1 and 313-2. In some embodiments, the plurality of recesses 323-1 and 313-2 are filled with the first portion 330, as shown in FIG. 4D, but the disclosure is not limited thereto. In some embodiments, the first portion 330 can be formed by a SEG method, but the disclosure is not limited thereto. Accordingly, the first portion 330 includes epitaxial semiconductor material, such as epitaxial silicon. In some embodiments, the first portion 330 can be un-doped epitaxial silicon. In other embodiments, the first portion 330 to can be doped with dopants of a conductivity type, which will be disclosed below. Additionally, a bottom surface of the first portion 330 is lower than a bottom surface of the mesh-like isolation structure 310.

Referring to FIG. 4E, a second portion 340 of each of the first and second semiconductor islands 320-1 and 320-2 is formed on each of the first portion 330 in each of the first openings 312-2 and the second opening 312-2. A height H2 of the second portion 340 is greater than a height H1 of the first portion 330, as shown in FIG. 4E. In some embodiments, the second portion 340 can be formed by a SEG method but the disclosure is not limited thereto. In some embodiments, the second portion 340 of the plurality of first semiconductor islands 320-1 and the second semiconductor island 320-2 includes epitaxial silicon, but the disclosure is not limited thereto. Further, the second portion 340 of the plurality of first semiconductor islands 320-1 and the second semiconductor island 320-2 can be doped with dopants of a conductivity type before, during, or after the SEG. The conductivity type can be a p type or an n type, depending on the product requirements. It should be noted that in some embodiments, when the second portion 340 is doped with the p type dopants, the first portion 330 is un-doped or doped with the n type dopants. In alternative embodiments, when the second portion 340 is doped with the n type dopants, the first portion 330 is un-doped or doped with the p type dopants. Briefly speaking, the second portion 340 is doped with dopants of a first conductivity type, the first portion 330 is un-doped or doped with dopants of a second conductivity type, and the first conductivity type and the second conductivity type are complementary with each other.

Accordingly, a semiconductor structure 300 is provided. Please refer to FIG. 4E and FIG. 5, wherein FIG. 5 is a top view of a portion of the semiconductor structure 300 in accordance with the second embodiment. The semiconductor structure 300 includes the substrate 302, the mesh-like isolation structure 310 disposed on the substrate 302, and the plurality of first semiconductor islands 320-1 disposed on the substrate 302. As shown in FIG. 4E, the substrate 302 includes the first region 304-1 for accommodation memory cells and the second the second region 304-2. The mesh-like isolation structure 310 further includes a plurality of first isolation structures 314-1 located in the first region 304-1 and at least a second isolation structure 314-2 located in the second region 304-2.

Each of the first isolation structures 314-1 includes a bottom surface 316B in contact with the substrate 302 and a top surface 316T opposite to the bottom surface 316B. Further, the top surface 316T is exposed, as shown in FIG. 4E. The top surface 316T has a width Wt1, the bottom surface 316B has a width Wb1, and the width Wb1 of the bottom surface 316B is greater than the width Wt1 of the top surface 316T, as shown in FIG. 4E. The second isolation structure 314-2 includes a bottom surface 318B in contact with the substrate 302 and a top surface 318T opposite to the bottom surface 318B. Similarly, the top surface 318T is exposed, as shown in FIG. 4E. The top surface 318T has a width Wt2, the bottom surface 318B has a width Wb2, and the width Wb2 of the bottom surface 318B is greater than the width Wt2 of the top surface 318T. The width Wt2 of the top surface 318T of the second isolation structure 314-2 is greater than the width Wt1 of the top surface 316T of the first isolation structures 314-1. The width Wb2 of the bottom surface 318B of the second isolation structure 314-2 is greater than the width Wb1 of the bottom surface 316B of the first isolation structures 314-1.

Still referring to FIGS. 4E and 5, the plurality of first semiconductor islands 320-1 are embedded within and separated from each other by the plurality of first isolation structures 314-1 in the first region 304-1. In some embodiments, a height-to-width aspect ratio of the plurality of first semiconductor islands 320-1 is greater than 10, but the disclosure is not limited thereto. According to the second embodiment, each of the first semiconductor islands 320-1 includes the first portion 330 in contact with the substrate 302 and the second portion 340 disposed on the first portion 330. As mentioned above, the height H2 of the second portion 340 is greater than the height H1 of the first portion 330. As shown in FIG. 4E, a bottom surface of the first portion 330 is lower than the bottom surface 316B of the first isolation structure 314-1. Further, the bottom surface of the first portion 330 can be taken as a bottom surface 322B of the first semiconductor islands 320-1, while atop surface of the second portion 340 can be taken as a top surface 322T of the first semiconductor islands 320-1.

Accordingly, each of the first semiconductor islands 320-1 includes the bottom surface 322B in contact with the substrate 302 and the top surface 322T opposite to the bottom surface 322B. Further, the top surface 322T is exposed, as shown in FIG. 4E. The top surface 322T has a width Wt3, the bottom surface 322B has a width Wb3, and the width Wb3 of the bottom surface 322B of the first semiconductor island 320-1 is less than the width Wt3 of the top surface 322T of the first semiconductor island 320-1, as shown in FIG. 4E.

In some embodiments, the semiconductor structure 300 further includes at least a second semiconductor island 320-2 disposed in the second region 304-2. Further, the second semiconductor island 320-2 is separated from the plurality of first semiconductor islands 320-1 by the second isolation structure 314-2. According to the second embodiment, the second semiconductor island 320-2 includes the first portion 330 in contact with the substrate 302 and the second portion 340 disposed on the first portion 330. As mentioned above, the height H2 of the second portion 340 is greater than the height H1 of the first portion 330. As shown in FIG. 4E, a bottom surface of the first portion 330 is lower than the bottom surface 318B of the second isolation structure 314-2. Further, the bottom surface of the first portion 330 can be taken as a bottom surface 324B of the second semiconductor island 320-2, while a top surface of the second portion 340 can be taken as a top surface 324T of the second semiconductor island 320-2.

Accordingly, the second semiconductor islands 320-2 includes the bottom surface 324B in contact with the substrate 302 and the top surface 324T opposite to the bottom surface 324B. Further, the top surface 324T is exposed, as shown in FIG. 4E. The top surface 324T has a width Wt4, the bottom surface 324B has a width Wb4, and the width Wb4 of the bottom surface 324B of the second semiconductor island 320-2 is less than the width Wt4 of the top surface 324T of the second semiconductor island 320-2, as shown in FIG. 4E. Further, both the width Wt4 of the top surface 324T and the width Wb4 of the bottom surface 324B of the second semiconductor island 320-2 are greater than the width Wt3 of the top surface 322T of the first semiconductor islands 320-1.

The second portion 340 of the first and second semiconductor islands 320-1 and 320-2 includes dopants of a first conductivity type, and the first portion 330 of the first and second semiconductor islands 320-1 and 320-2 is un-doped or includes dopants of a second conductivity type. As mentioned above, the first conductivity type and the second conductivity type are complementary with each other.

According to the semiconductor structure 300 and the method 12 for preparing the same, the mesh-like isolation structure 310 (including the first isolation structures 314-1 and the second isolation structure 314-2) is formed on the substrate 302 before the forming of the first and second semiconductor islands 320-1 and 320-2. Due to the mesh-like configuration, a structural strength of each of the first isolation structures 314-1 and the second isolation structure 314-2 is improved such that collapsing and toppling are prevented. Further, the plurality of first semiconductor islands 320-1, which serve as active region for memory cells, can be easily formed in the mesh-like isolation structure 310. Accordingly, collapsing and toppling of the thin, slim first semiconductor islands 320-1 are avoided, and thus reliability and performance of a device that includes the semiconductor islands are improved. Additionally, the first portion 330 of the first and second semiconductor islands 320-1 and 320-2 provides better electrical isolation between the substrate 302 and the second portion 340 of the first and second semiconductor islands 320-1 and 320-2.

Further, the width Wb1 of the bottom surface 316B of the first isolation structures 314-1 is greater than the width Wt1 of the top surface 316T of the first isolation structures 314-1, and the width Wb2 of the bottom surface 318B of the second isolation structure 314-2 is greater than the width Wt2 of the top surface 318T of the second isolation structure 314-2. The trapezoidal configuration of the first and second isolation structures 314-1 and 314-2 increases resistance in the substrate 302 along sidewalls and the bottom surface 316B and 318B of the first and second isolation structures 314-1 and 314-2. Accordingly, the mesh-like isolation structure 310 provides better electrical isolation.

In the present disclosure, the mesh-like isolation structure 210/310 are formed on the substrate 202/302. Due to the mesh-like configuration, a structural strength is improved such that collapsing and toppling are prevented. Further, the plurality of semiconductor islands 220-1/320-1, which serve as an active region for memory cells, can be easily formed in the mesh-like isolation structure 210/310. Accordingly, collapsing and toppling of the thin, slim semiconductor islands 220-1/320-1 are avoided, and thus reliability and performance of a device that includes the semiconductor island structure are improved.

In contrast, with a comparative method, the semiconductor islands are formed on the substrate and vacancies between the semiconductor islands are subsequently filled with the isolation structure. The semiconductor islands often topple or collapse due to their thin and slim configuration and due to the stress generated during the forming of the isolation structure, and thus reliability and performance of a device that includes the first and second island structures are adversely impacted.

One aspect of the present disclosure provides a semiconductor structure. The semiconductor structure includes a substrate, a plurality of first isolation structures disposed on the substrate, and a plurality of first semiconductor islands disposed on the substrate and separated from each other by the plurality of first isolation structures. In some embodiments, each of the plurality of first isolation structures includes a first bottom surface in contact with the substrate and a first top surface opposite to the first bottom surface. In some embodiments, a width of the first bottom surface is greater than a width of the first top surface.

Another aspect of the present disclosure provides a method for preparing a semiconductor structure. The method includes the following steps. A substrate is provided. A mesh-like isolation structure is formed on the substrate. In some embodiments, the mesh-like isolation structure includes a plurality of first openings exposing the substrate. A plurality of first semiconductor islands are formed to fill the plurality of first openings. In some embodiments, each of the plurality of first semiconductor islands has a bottom surface in contact with the substrate and a top surface opposite to the bottom surface. In some embodiments, a width of the top surface is greater than a width of the bottom surface.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor structure comprising:
a substrate;
a plurality of first isolation structures disposed on the substrate; and
a plurality of first semiconductor islands disposed on the substrate and separated from each other by the plurality of first isolation structures,
wherein each of the plurality of first isolation structures to comprises a first bottom surface in contact with the substrate and a first top surface opposite to the first bottom surface, and a width of the first bottom surface is greater than a width of the first top surface.

2. The semiconductor structure of claim 1, wherein a height-to-width aspect ratio of the plurality of first semiconductor islands is greater than 10.

3. The semiconductor structure of claim 1, wherein each of the plurality of first semiconductor islands comprises a first portion disposed on the substrate and a second portion disposed on the first portion, and a height of the second portion is greater than a height of the first portion.

4. The semiconductor structure of claim 3, wherein a bottom surface of the first portion is lower than the first bottom surface of the first isolation structure.

5. The semiconductor structure of claim 3, wherein the second portion is electrically isolated from the substrate by the first portion.

6. The semiconductor structure of claim 5, wherein the second portion comprises dopants of a first conductivity type.

7. The semiconductor structure of claim 6, wherein the first portion is un-doped.

8. The semiconductor structure of claim 6, wherein the first portion comprises dopants of a second conductivity type complementary to the first conductivity type.

9. The semiconductor structure of claim 1, further comprising:
a second isolation structure disposed on the substrate; and
at lease a second semiconductor island disposed on the substrate and separated from the plurality of first semiconductor islands by the second isolation structure,
wherein the second isolation structure comprises a second bottom surface in contact with the substrate and a second top surface opposite to the first bottom surface, and a width of the second bottom surface is greater than a width of the second top surface.

10. The semiconductor structure of claim 9, wherein the width of the second bottom surface of the second isolation structure is greater than the width the first bottom surface of the first isolation structure, and the width of the second top surface of the second isolation structure is greater than the width the first top surface of the first isolation structure.

11. A method for preparing a semiconductor structure, comprising:
providing a substrate;
forming a mesh-like isolation structure on the substrate, wherein the mesh-like isolation structure comprises a plurality of first openings exposing the substrate; and
forming a plurality of first semiconductor islands to fill the plurality of first openings,
wherein each of the plurality of first semiconductor islands has a bottom surface in contact with the substrate and a top surface opposite to the bottom surface, and a width of the top surface is greater than a width of the bottom surface.

12. The method of claim 11, wherein the forming of the mesh-like isolation structure further comprises:
forming an insulating layer on the substrate; and
removing portions of the insulating layer to form the plurality of first openings.

13. The method of claim 11, further comprising removing portions of the substrate exposed through the plurality of first openings of the mesh-like isolation structure to form a plurality of recesses in the substrate, wherein each of the plurality of recesses is under and coupled to one of the plurality of first openings.

14. The method of claim 13, wherein the forming of the plurality of first semiconductor islands further comprises:
forming a first portion of each of the plurality of first semiconductor islands in each recess; and
forming a second portion of each of the plurality of first semiconductor islands on each first portion in each first opening.

15. The method of claim 14, wherein the second portion is doped with a first conductivity type, and the first portion is un-doped.

16. The method of claim 14, wherein the second portion is doped with dopants of a first conductivity type, the first portion is doped with dopants of a second conductivity type, and the first conductivity type and the second conductivity type are complementary with each other.

17. The method of claim 14, where a bottom surface of the first portion is lower than a bottom surface of the mesh-like isolation structure.

18. The method of claim 14, wherein a height of the second portion is greater than a height of the first portion.

19. The method of claim 11, wherein the mesh-like isolation structure further comprises at least a second opening, wherein a width of the second opening is greater than a width of each of the plurality of first openings.

20. The method of claim 19, further comprising forming a second semiconductor island to fill the second opening simultaneously with the forming of the plurality of first semiconductor islands.
